(19) United States
(12) Patent Application Publication
(10) Pub. No.: US 2012/0097529 A1
(43) Pub. Date: Apr. 26, 2012

(54) MAGNETRON COATING MODULE AND MAGNETRON COATING METHOD

(75) Inventors: Andreas Pflug, Braunschweig (DE); Michael Siemers, Braunschweig (DE); Volker Sittinger, Braunschweig (DE); Bernd Szyszka, Braunschweig (DE); Stephan Ulrich, Braunschweig (DE)

(73) Assignee: Fraunhofer-Gesellschaft Zur Foerderung Der Angewandten Forschung E.V., Munich (DE)

(21) Appl. No.: 13/138,810

(22) PCT Filed: Mar. 25, 2010
(86) PCT No.: PCT/EP2010/001871

§ 371 Date: Nov. 21, 2011

(30) Foreign Application Priority Data
Mar. 31, 2009 (DE) 10 2009 015 737.9

(51) Int. Cl. C23C 14/35

(52) U.S. Cl. 204/192.15; 204/298.12; 204/192.12

(57) ABSTRACT

The invention relates to a new basic technology for magnetron sputtering of ceramic layers, in particular for optical applications. The new concept enables the construction of magnetron sputtering sources which, in comparison with the known methods, such as reactive DC-, MF- or RF magnetron sputtering or the magnetron sputtering of ceramic targets, enables significantly improved precision in the deposition of ceramic layers at an exactly defined rate and homogeneity and also with very good reproducibility.

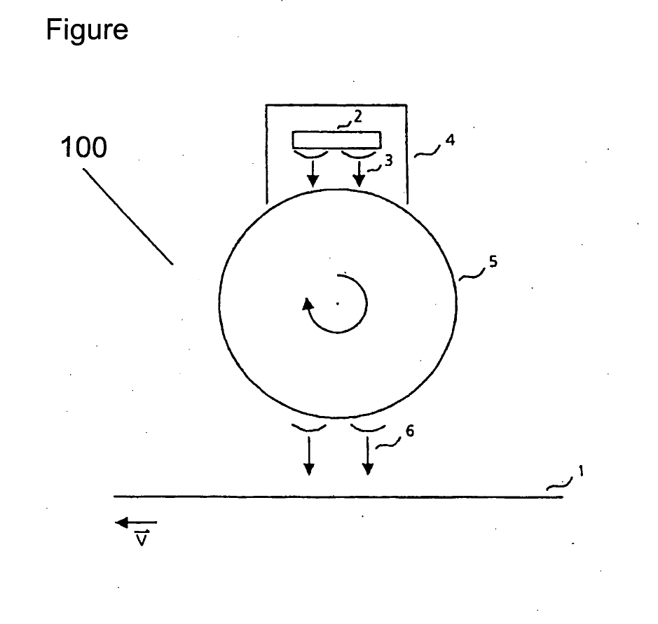

The invention relates to a new basic technology for magnetron sputtering of ceramic layers, in particular for optical applications. The new concept enables the construction of magnetron sputtering sources which, in comparison with the known methods, such as reactive DC-, MF- or RF magnetron sputtering or the magnetron sputtering of ceramic targets, enables significantly improved precision in the deposition of ceramic layers at an exactly defined rate and homogeneity and also with very good reproducibility.

Magnetron sputtering sources have proved to be extremely efficient coating tools in the last few years for manufacturing thin film systems on an industrial scale.

Optical thin film systems which use the principle of interference, e.g. for optical filters and architectural glass coatings, hereby require as precise maintenance of the specific layer properties as possible and this both with respect to the coating on large substrates and with respect to temporal constancy over long production periods.

For industrial manufacture, in particular such coating processes which operate per se with a specific stability are thereby relevant, such as for instance magnetron sputtering of ceramic targets or reactive magnetron sputtering with reactive excess in compound mode.

In addition, control circuits which enable maintenance of the layer properties even over long production time periods are used. The control requirement hereby increases greatly with the sought precision of the optical properties of the layer system and with the number of individual layers in the layer system.

The sought precision of the optical properties of the layer system is thereby defined generally by permissible deviations between transmission- and reflection spectra of a layer system design and the deposited layer system.

With increasing precision requirements, in particular control of the rate and of the layer thickness and also ensuring a constant refractive index in the deposition of the respective layer is increasingly of importance. In general, an in situ control is implemented in the field of fine- and precision optics, whilst an ex situ control is sufficient in the field of architectural glass coating in order to compensate for long-term drifts.

In the case of reactive magnetron sputtering as deposition method, it is known that the rate and hence the layer thickness depend greatly upon the process conditions with a prescribed time duration of the deposition process. In particular variations in total pressure (Pflug, A.: “Simulation des reaktiven Magnetron-Sputterns” (Simulation of reactive magnetron sputtering), Dissertation, Justus-Liebig University Gieβen, 2006) and reactive gas partial pressure (Sullivan, B. T.; Clarke, G. A.; Akiyama, T.; Osborne, N.; Ranger, M.; Dobrowolski, J. A.; Howe, L.; Matsumoto, A.; Song, Y.; Kikuchi, K.: “High-rate automated deposition system for the manufacture of complex multilayer systems”, in: Applied Optics 39 (2000), pp. 157-67), as can occur for example in substrate movements, lead to changes in the coating rate and the refractive index.

In the case of sputtering of ceramic targets, the conditions are simpler. Here, the ceramic target already approximately provides the correct stoichiometry, addition of reactive gas to the sputtering gas is however also required here in order to achieve stoichiometric and highly transparent layers. This addition of reaction gas during sputtering of ceramic targets also leads to the fact that coating rate and homogeneity vary temporally, caused by pressure variations and long-term drifts of the target state, which requires metrological detection of these processes and readjustment of the plant adjustable variables. From the point of view of process stability, the addition of reactive gas during sputtering of ceramic targets is hence undesired.

The most widely used technology for depositing layer systems in the field of precision optics, is batch plants (Scherer, M.; Pistner, J.; Lehnert, W.: “Innovative production of high-quality optical coatings for applications in optics and optoelectronics”, in: SVC Annual Technical Conference Proceedings 47 (2004), pp. 179-82). These generally use the technology of reactive electron beam evaporation with additional plasma activation for the deposition of multilayer systems. Materials typically used hereby are e.g. SiO₂, Ta₂O₅, TiO₂, ZrO₂, HfO₂, Al₂O₃ (Zültzke, W.; Schraner, E.; Stolze, M.: “Materialen für die Brillenbeschichtung in Aufdampfanlagen” (Materials for spectacle coating in evaporation coating plants), in: Vakuum in Forschung and Praxis 19 (2007), pp. 24-31).

The technology allows the deposition of dense and smooth layers based on the favourable influence of plasma activation on the layer growth (Ebert, J.: “Ion-assisted reactive deposition process for optical coatings”, in: Surface and Coatings Technology 43/44 (1990), pp. 950-62).

Because of the lobar characteristic of the evaporator and the laterally varying strength of the plasma activation, lateral inhomogeneities in the layer thickness and in the optical constants on a stationary substrate result. By arrangement of the substrates on a bent dome and specific substrate rotations, these influences are however greatly reduced.

Typical substrates have diameters of 5 to 8 cm, with which piece numbers of a few 100 components can be achieved in one coating run (Leybold Optics: Technical Features Syrus III, http://www/sputtering.de/pdf/syrusiii-tf_en.pdf; 2005). The fitting of a dome with substrates is effected by hand. An increase in the substrate size is only possible by scaling-up the entire structure.

The layer thickness of the respective layer is generally determined by an in situ control, e.g. by measuring the transmission. Upon achieving the target layer thickness, the deposition is stopped. The achieved growth rates are in the range of 0.5 nm/s. The maximum achievable layer thickness or service life is limited by the filling of the evaporator crucible.

Sputtering methods for the production of layer systems are likewise used in the field of precision optics. On the basis of the likewise increased particle energies in comparison with pure evaporation coating, they offer the possibility of depositing dense, smooth, absorption-free and low-defect layers.

Several variants of sputtering methods are known:

Reactive DC sputtering is accompanied by strong arc formation and has the problem of the disappearing anode (Hagedorn, H.: “Solutions for high productivity high performance coating systems”, in: SPIE 5250 (2004), pp. 493-501).

Radio frequency (RF) sputtering has therefore proved its worth in the past as a standard process for sputtering oxides. This method enables defined deposition of optical multilayer systems of ceramic targets with in situ control (Sullivan, B. T.; M.; Dobrowolski, J. A.: “Deposition error compensation for optical multilayer coatings, II. Experimental results—sputtering system”, in: Applied Optics 32 (1993), pp. 2351-60): Good temporal stability of the deposition rate is hereby achieved. The process is unsuitable for practical applications due to the significantly lower coating rate (about 0.1 nm/s) relative to DC sputtering processes and due to problems in scaling-up the technology.

In Sullivan, B. T.; Clarke, G. A.; Akiyama, T.; Osborne, N.; Ranger, M.; Dobrowolski, J. A.; Howe, L.; Matsumoto, A.; Song, Y.; Kikuchi, K.: “High-rate automated deposition system for the manufacture of complex multilayer systems”, in: Applied Optics 39 (2000), pp. 157-67, reactive MF sputtering for deposition of high- and low-refractive index oxides is presented as a further possibility. In the case of the relevant materials (SiO₂ as low-refractive index layer and high-refractive index oxides), coating rates up to 0.6 nm/s are hereby achieved. It is crucial for achieving layers with the desired optical properties which are constant during the deposition to ensure a constant oxygen partial pressure by corresponding control, in particular in the switch-on processes and substrate movements. By means of this procedure and optical in situ monitoring of the coating, complex optical layer systems can be achieved. Substrates in the format 13×13 cm² are reported as typical substrate size. Good lateral layer thickness homogeneity is made possible by substrate rotation and the use of a mask.

A further variant of a sputtering method, the so-called METAMODE™ method, is presented for example in Lehan, J. P.; Sargent, R. B.; Klinger, R. E.: “High-rate aluminum oxide deposition by MetaMode™ reactive sputtering”, in: Journal of Vacuum Science and Technology A 10 (1922), pp. 3401-6, and Clarke, G.; Adair, R.; Erz, R.; Hichwa, B.; Hung, H.; Le Febvre, P.; Ockenfuss, G.; Pond, B.; Seddon, I.; Stoessel, C.; Zhou, D.: “High precision deposition of oxide coatings”, in: SVC Annual Technical Conference Proceedings 43 (2000), pp. 244-9. These publications are the basis for U.S. Pat. No. 4,851,095 A of the company OCLI (Optical Coating Laboratory, Inc.). The concept is based on sputtering of metals at a high rate and subsequent oxidation of the metal layers in the O₂ plasma of a plasma source. The conversion is effected via rotating plate units with a high rotational speed. In this way, the thickness of the sputtered metallic individual layers is only a few layers of atoms, so that oxidation of these layers to form optically high-quality metal oxide layers is possible.

The plasma source is situated next to the magnetron coating zone in this arrangement. In this way, the advantageous properties of the sputtering of metallic targets, with respect to high rate, very good homogeneity, reproducibility and long-term stability, are transferred to the production of dielectric layers. The method is distinguished by very high deposition rates of up to 10.5 nm/s (Lehan, J. P.; Sargent, R. B.; Klinger, R. E.: “High-rate aluminum oxide deposition by MetaMode™ reactive sputtering”, in: Journal of Vacuum Science and Technology A 10 (1992) pp. 3401-6).

A similar method is described in documents WO 2004/050944 A2, WO 2004/050944 A3, US 2006/0151312 A1, EP 01 592 821 A2 and DE 103 47 521 A1: here, the reactive MF sputtering in the transition region is supplemented by a plasma subsequent treatment in order to improve in particular the optical quality of the layers. The MF process is hereby operated at a controlled O₂ partial pressure so that the advantage of the stable coating rate during sputtering of a metallic target without reactive gas is not used. Here also, the process is repeated cyclically until the desired target layer thickness. Examples of optical layer systems which were deposited with this system can be found in Scherer, M.; Pistner, J.; Lehnert, W.: “Innovative production of high-quality optical coatings for applications in optics and optoelectronics”, in: SVC Annual Technical Conference Proceedings 47 (2004), pp. 179-82), and Hagedorn, H.: “Solutions for high productivity high performance coating systems”, in: SPIE 5250 (2004), pp. 493-501). The coating rate is in the range of 0.45 to 0.7 nm/s, the substrate size is up to 15 cm in diameter.

In the field of architectural glass coating, a document is known (Szyszka, B.; Pflug, A.; Fraunhofer-Gesellschaft zur Forderung der angewandeten Forschung e.V. (Proprietor): “Verfahren and Vorrichtung zum Magnetronsputtern” (Method and device for magnetron sputtering), DE 103 59 508 B4, in which a device and a method for magnetron sputtering is indicated. In this patent specification, two processes are combined. In the primary sputtering process, a layer is deposited on the substrate by sputtering a rotating tubular target. In a secondary process, precisely this tubular target is coated with an additional material component, e.g. by sputtering with a metallic target in an inert atmosphere. By means of in situ X-ray fluorescence measurements of the material coating of the rotating target with the additionally applied component and by arranging a mass balance, the coating rate can then be adjusted exactly.

For the highest requirements in the layer quality, Scherer, M.; Pistner, J.; Lehnert, W.: “Innovative production of high-quality optical coatings for applications in optics and optoelectronics”, in: SVC Annual Technical Conference Proceedings 47 (2004), pp. 179-82, and Hagedorn, H.: “Solutions for high productivity high performance coating systems”, in: SPIE 5250 (2004), pp. 493-501, e.g. for use in laser mirrors and X-ray lens systems, the method of ion beam sputter deposition is used (Gawlitza, P.; Braun, S.; Leson, A.; Lipfert, S.; Nestler, M.: “Herstellung von Präzisionsschichten mittels lonenstrahlsputtern” (Production of precision layers by means of ion beam sputtering), in: Vakuum in Forschung und Praxis 19/2 (2007), pp. 37-43) (ISBD, ion beam sputter deposition). A target is hereby sputtered by a noble gas ion beam (Ar, Kr, Xe) with adjustable beam strength. Typical process pressures are in the range of 10 to 50 mPa and hence are lower than with conventional sputtering methods. The sputtered elements therefore experience impacts extremely rarely and maintain their generally advantageous kinetic energy until impinging on the substrate. By controlling the ion beam to constant beam strentgth and operation of the target in the metallic mode, excellent long-term stability of the rate is achieved. As a function of the material, the rate is however merely 0.02 to 0.4 nm/s.

By means of screens (partially moved) and substrate movement, very good lateral homogeneity, in particular also on curved surfaces, can be achieved. In addition, also layers with specific gradients can be deposited by suitable substrate movements. The substrate sizes are in the range of 20×20 cm². Narrow rectangular substrates can be coated homogeneously up to an edge length of 50 cm.

Deposition of oxides is possible by the addition of oxygen close to the substrate, the sputtering process on the target remaining however in the metallic mode.

As an example of a non-reactive deposition, an EUV mirror with 60 Mo/Si bilayers is described in Gawlitza, P.; Braun, S.; Leson, A.; Lipfert, S.; Nestler, M.: “Herstellung von Präzisionsschichten mittels lonenstrahlsputtern” (Production of precision layers by means of ion beam sputtering), in: Vakuum in Forschung und Praxis 19/2 (2007), pp. 37-43). Dielectric SiO₂/TiO₂ multilayers for an IR lens system are shown as an example of a reactive deposition.

It is common to almost all already known methods that, on the one hand, the coating rate is influenced greatly by the reactive gas partial pressure which in turn depends upon process variations, e.g. based on the substrate movement, switch-on processes etc. On the other hand, long-term drifts of the sputter target state lead to a long-term temporal variation in the coating rate which must be taken into account during process control.

In the case of the MetaMode method, this dependence does not occur, however this method is suitable only for batch coating plants but not for in-line coating plants.

It is therefore the object of the present invention to provide a magnetron coating module and a method which do not have the above-mentioned problematic dependencies and which are able to produce layers with extremely good homogeneity and reproducibility.

In particular, it is the object of the present invention consequently to be able to dispense with an in situ control of the layer properties and in particular of the thickness of the respective layer, as is used as standard in the field of deposition of precision-optic layer systems.

This object is achieved, with respect to the magnetron coating module, by the features of patent claim 1 and, with respect to the magnetron coating method, by the features of patent claim 5. The respective dependent claims thereby represent advantageous developments.

The invention relates to a new process technology for magnetron sputtering of dielectric layers, in particular for optical applications. The new concept provides a magnetron coating module which enables reactive deposition of layers at a defined rate even on large surfaces.

According to the invention, a magnetron coating module is hence provided, which comprises
a) a first coating source,
b) a rotating target as auxiliary substrate which is disposed between the first coating source and the region for receiving the substrate,
c) a magnetron, the rotating target forming the cathode of the magnetron, and also
d) a gas chamber separation between first coating source and the coating region on the substrate,
   at least the surface of the rotating target (5) consisting of a material which is not deposited or only to a small extent on the substrate during sputtering.

With the magnetron coating module according to the invention, relative to conventional coating modules, significantly improved stability of the coating rate and of the homogeneity can be achieved. It is ensured at the same time that only the materials which are intended to be deposited are deposited on the substrate. Contamination caused by the sputtering cathode (which occur for example with metal cathodes) can therefore be avoided.

The rotating target (tubular target) as auxiliary substrate preferably consists of a material which has a low sputtering rate and, when it is sputtered, is not incorporated or only to a small extent in the deposited layer. There are included herein, for example materials which, with the conditions prevailing during the sputtering process (e.g. the gases contained in the atmosphere), form gaseous compounds which are not deposited on the target in the further process. One possibility is the use of carbon as material for the tubular target. Preferably, it is achieved that the sputtered material forms a gaseous compound with the reactive gas which is not incorporated or only to a small extent in the deposited layer, e.g. CO₂ in the case of a carbon auxiliary target. The gaseous compound can then be pumped away.

The first coating source is preferably a source which, with respect to the homogeneity of the coating and to the constancy of the coating rate, has very high precision. This source can be achieved for example in the form of a planar magnetron in which a metallic target is sputtered in an inert atmosphere. For such a source, the particle flow to the substrate can be indicated very precisely and also made to accord with a model.

According to the invention, a method for coating a substrate with a magnetron coating module according to the invention is likewise provided, in which coating of the rotating target is implemented, in a first step, with the first coating source and, in a second step, the coating is removed from the rotating target with the help of the magnetron and is deposited on the substrate.

The deposition of a layer is hence effected in a two-stage process:

Firstly, coating of the auxiliary substrate is implemented by the first coating source. This coating is removed from the auxiliary substrate by the magnetron and is deposited with the correct stoichiometry on the substrate.

A series of advantages results by means of the method according to the invention:

An extremely stable rate of the reactively operated magnetron results due to the constant coating of the auxiliary target and the subsequent complete removal. In particular variations in pressure, e.g. by substrate movements, now have no influence on the stability of the coating rate. Hence new possibilities are opened up for use of this technology in the field of fine- and precision optics and also in the field of large-area coating. An in situ control for rate stabilisation and layer thickness control can be dispensed with in favour of a simple, robust and economical time-controlled deposition. Merely an ex situ control is possibly still required for compensation of long-term drifts. However, this can also be replaced by suitable storing of the time-dependency of the rate for the sputtering of the metallic target.

In total, the new technology enables transition to in-line coating processes for fine- and precision optics in order to coat larger substrates at a higher throughput. What is established technically in the field of architectural glass coating at present is the coating on substrates in the format of up to 3.21×6.00 m² with cycle times below 1 min.

Relative to evaporation coating processes, an increase in plant operating time between the maintenance cycles results as an additional advantage since sputtering methods in general can have a higher service life than evaporation methods which are limited by the maximum crucible filling and size.

In a preferred embodiment, the removal of the coating from the rotating target is effected at excess power of the magnetron, i.e. the power of the magnetron is adjusted to be so high that complete removal of the coating effected previously in the first step is ensured. Hence, adjustment of the sputtering rate at which the substrate is coated is effected not directly by varying the parameters of the actual sputtering process (which is effected here with the magnetron) but by adjusting the operating parameters of the coating source for the rotating target. By means of the excess power of the magnetron, it is ensured therefore that the same continuous quantity is always deposited on the substrate so that the coating is deposited in the correct stoichiometry on the substrate.

Preferably, a further condition for high precision is that the material applied by the first target onto the rotating target (auxiliary substrate) is removed again completely from this in the second sputtering process. The rotating magnetron must, in this case, be operated with excess power.

Consequently, it is ensured that the erosion rate of the auxiliary target is equal to the coating rate of the substrate.

In a further preferred embodiment, the coating of the rotating target is effected by sputtering a metallic target, preferably a target selected from the group consisting of Si, Ta, Ti, Zr, Hf, Al, Zn, Sn, Nb, V, W, Bi, Sb, Mo, Mg, Ca, Se, In, Ni, Cr, Mn, Te, Cd and/or alloys hereof by means of a planar magnetron as coating source.

The coating of the rotating target is thereby effected advantageously in an inert atmosphere, inert gases which are familiar to the person skilled in the art and suitable for the sputtering process being used, such as e.g. Ar, Kr, Xe, Ne, Ar being the most usual gas by far.

It is likewise preferred if the removal process of the rotating target is implemented in a reactive gas atmosphere, the reactive gas atmosphere preferably comprising O₂, N₂, H₂S, N₂O, NO₂, CO₂ or mixtures hereof or consisting thereof.

Likewise, the atmospheres used during the sputtering process can comprise both reactive and inert gases (e.g. Ar+O₂). It is likewise advantageous if the pressure of the atmosphere, in the first step, is 0.2 to 20 Pa, preferably 0.5 to 10 Pa, particularly preferred 1.0 to 5 Pa and/or, in the second step, 0.05 to 5 Pa, preferably 0.1 to 3 Pa, particularly preferred 0.2 to 2 Pa.

Advantageous speeds of rotation of the rotating target are thereby between 1 to 100 1/min, preferably 2 to 50 1/min, particularly preferred 5 to 25 1/min, relative to the surface of the rotating target.

The first coating source is thereby dimensioned or set such that the rotating target is coated at a rate of 0.1 to 200 nm*m/min, preferably 0.5 to 100 nm*m/min, particularly preferred 1 to 50 nm*m/min.

Preferably, the material of the surface of the rotating target forms a gaseous compound with the reactive gas during the sputtering, which compound is not incorporated or only to a small extent in the layer being deposited.

The present invention is explained in more detail with reference to the accompanying FIGURE without wishing to restrict this to the parameters represented in the FIGURE.

The magnetron coating module 100 consists of the following components:
1. a first coating source (2, 3);
2. a rotating target, disposed as auxiliary substrate 5 between this first coating source and the region which is provided for receiving the substrate 1 to be coated;
3. a magnetron (5, 6), the auxiliary substrate 5 forming a cathode for this magnetron and being formed, in the present case as an example, from carbon, and also
4. a gas chamber separation 4 between first coating source 2, 3 and the coating region on the substrate 6.

A continuous coating process of the substrate 1 is represented in the FIGURE, the substrate being guided through below the magnetron at the velocity v. Likewise, a batch operation of the magnetron coating module 100 is however possible. The FIGURE shows, in the central part thereof, a cylindrical auxiliary substrate 5 which rotates about its longitudinal axis. Below the cylindrical auxiliary substrate, the substrate 1 to be coated is disposed. This substrate can concern for example architectural glass. The substrate 1 is moved through below the coating plant. As a result of a voltage applied to the auxiliary substrate 5, plasma is ignited in the region 6 between the auxiliary substrate 5 and the substrate 1. The auxiliary substrate hence forms a bar cathode from which material is sputtered, which material coats the substrate 1 connected as anode. In the region 6, a mixture of inert and reactive gas is situated and allows deposition of a multicomponent layer. On the opposite side of the auxiliary substrate 5, a planar magnetron 2, 3 is situated in a screen 4. In this case, the auxiliary substrate 5 is connected as anode which is coated in the plasma region with material of the planar sputtering cathode 2. The gas phase in the region 3 comprises exclusively inert gas so that the deposition rate in the region 3 can be determined from the known sputtering rates and the electrical parameters. The coating rate on the substrate 1 results from the mass balance on the auxiliary substrate 5. In addition to the known coating rate in the region 3, also the material coating after the sputtering process in the region 6 is required for this purpose.

1-13. (canceled)

14. A magnetron coating module, comprising
a) a first coating source;
b) a rotating target as auxiliary substrate which is disposed between the first coating source and the region for receiving the substrate (1);
c) a magnetron, the rotating target forming the cathode of the magnetron; and also
d) a gas chamber separation between first coating source and the coating region on the substrate,
wherein at least the surface of the rotating target consists of a material which is not deposited or only to a small extent on the substrate during sputtering.

15. The magnetron coating module according to claim 14, wherein at least the surface of the rotating target comprises carbon, preferably consists of carbon or a carbon-containing material.

16. The Magnetron coating module according to claim 14, wherein the first coating source is a planar magnetron.

17. A method for coating a substrate with a magnetron coating module according to claim 14, in which coating of the rotating target is implemented, in a first step, with the first coating source and, in a second step, the coating is removed from the rotating target with the help of the magnetron and is deposited on the substrate.

18. The method according to claim 17, wherein removal of the coating completely from the rotating target is effected at excess power of the magnetron.

19. The method according to claim 17, wherein the coating of the rotating target is effected by sputtering a metallic target, preferably a target selected from the group consisting of Si, Ta, Ti, Zr, Hf, Al, Zn, Sn, Nb, V, W, Bi, Sb, Mo, Mg, Ca, Se, In, Ni, Cr, Mn, Te, Cd and/or alloys hereof by means of a planar magnetron as coating source.

20. The method according to claim 17, wherein the coating process of the rotating target is implemented in an inert atmosphere.

21. The method according to claim 17, wherein the removal process of the rotating target is implemented in an inert or reactive gas atmosphere or in an atmosphere comprising a reactive and inert gas.

22. The method according to claim 21, wherein the reactive gas atmosphere comprises gases selected from the group consisting of O₂, N₂, H₂S, N₂O, NO₂, CO₂ and mixtures hereof.

23. The method according to claim 17, wherein the pressure of the atmosphere, in the first step, is 0.2 to 20 Pa, and/or, in the second step, 0.05 to 5 Pa.

24. The method according to claim 17, wherein the pressure of the atmosphere, in the first step, is 0.5 to 10 Pa, and/or, in the second step, 0.1 to 3 Pa.

25. The method according to claim 17, wherein the pressure of the atmosphere, in the first step, is 1.0 to 5 Pa and/or, in the second step, 0.2 to 2 Pa.

26. The method according to claim 17, wherein the speed of rotation of the rotating target is 1 to 100 1/min.

27. The method according to claim 17, wherein the speed of rotation of the rotating target is 2 to 50 1/min.

28. The method according to claim 17, wherein the speed of rotation of the rotating target is 5 to 25 1/min.

29. The method according claim 17, wherein the rotating target is coated at a rate of 0.1 to 200 nm*m/min.

30. The method according to claim 17, wherein the rotating target is coated at a rate of 0.5 to 100 nm*m/min.

31. The method according to claim 17, wherein the rotating target is coated at a rate of 1 to 50 nm*m/min.

32. The method according to claim 17, wherein the material of the surface of the rotating target forms a gaseous compound with the reactive gas during the sputtering, which compound is not incorporated or only to a small extent in the layer being deposited.
